(19) United States
(12) Patent Application Publication
(10) Pub. No.: US 2022/0386506 A1
(43) Pub. Date: Dec. 1, 2022

(54) HEAT-SINK CHAMBERS

(71) Applicant: Hewlett-Packard Development Company, L.P., Spring, TX (US)

(72) Inventors: Hao-Wu Yang, Taipei City (TW); Ai-Tsung Li, Taipei City (TW); Hung-Wen Chang, Taipei City (TW); Chien-Tu Cheng, Taipei City (TW)

(73) Assignee: Hewlett-Packard Development Company, L.P., Spring, TX (US)

(21) Appl. No.: 17/775,908

(22) PCT Filed: Nov. 14, 2019
(86) PCT No.: PCT/US2019/061431

§ 371 Date: May 11, 2022

(51) Int. Cl. H05K 7/20; G06F 1/20

(52) U.S. Cl. CPC H05K 7/20263; G06F 1/203

(57) ABSTRACT

Example implementations relate to heat-sink chambers. For instance, in an example a heat-sink can include a body including a first surface and a second surface, where the body defines: a chamber that extends from the first surface through a portion of a total thickness of the body; an opening in the second surface; and a channel that extends from the chamber through a remaining portion of the total thickness of the body to the opening to couple the chamber to the opening.

### BACKGROUND

Computing devices include laptop computers, desktop computers, various phones such as mobile phones, etc. The computing devices may include various components that generate heat during operation of the computing device. Examples of heat-generating components include integrated circuit chips (IC)s, central processing units, graphical processing units, and powers sources, among other types of heat-generating components.

### BRIEF DESCRIPTION OF THE DRAWINGS

FIG. 1 illustrates an example of a heat-sink including a chamber according to the disclosure.

FIG. 2 illustrates an example of a heat-dissipation system with a heat-sink including a chamber according to the disclosure.

FIG. 3 illustrates another example of a heat-dissipation system with a heat-sink including a chamber according to the disclosure.

FIG. 4 illustrates an example of a computing device including a heat-dissipation system with a heat-sink including a chamber according to the disclosure.

FIG. 5 illustrates another example of a computing device including a heat-dissipation system with a heat-sink including a chamber according to the disclosure.

### DETAILED DESCRIPTION

As mentioned, computing devices such as laptops, cellular phones and other computing devices include heat-generating components that generate heat during operation of the computing devices. Examples of heat-generating components including integrated circuits, central-processing units, graphics processing units, and/or power sources, among others. However, performance of the computing device may be reduced at high temperatures, for instance by throttling of a central-processing unit or otherwise. As such, effective dissipation of heat generated by the heat-generating components may be sought.

For instance, some approaches may employ a heat-sink in contact with a heat-generating component in an effort to dissipate heat from the heat-generating component. In such approaches, a thermal interface material (TIM) can be present at an interface between the heat-sink and the heat-generating component. For example, a TIM can be disposed in a space between the heat-generating component and the heat-sink. However, the TIM may be subjected to temperature variations/physical forces such as those that may occur during transport of the computing device to a point of sale/consumer. Such temperature variations/forces may cause the TIM to degrade and/or even become liquified and therefore move out of the space between the heat-generating component and the heat-sink. As a result, heat may not readily dissipate from the heat-generating component.

Other approaches may attempt to apply a TIM to a computing device once the computing device is received at a point of sale and/or at the end consumer. However, such approaches may necessitate disassembly of various components of the computing device to permit physical access to and application of the TIM to computing device. For instance, a heat-sink of the computing device may be removed from the computing device to permit access to a space between a heat-generating component and the heat-sink (when installed on the computing device). However, disassembly of various components of the computing device to permit application of the TIM can be time-consuming, lead to damage to components of the computing device, etc.

Accordingly, the disclosure is directed to heat-sink chambers. For instance, in various examples, a heat-sink can include a body having a first surface and a second surface, where the body defines a chamber, an opening, and a channel. For example, the chamber can extend from a first surface of the body through a portion of a total thickness of the body and the channel can extend from the chamber through a remaining portion of the total thickness of the body to the opening in the second surface. As such, the channel can be in fluid communication with the chamber and the opening. As detailed herein, a TIM can be disposed in the chamber and ejected from the opening, in contrast to other approaches such as those detailed above that necessitate TIM application during manufacture and/or disassembly of various components to permit application of TIM.

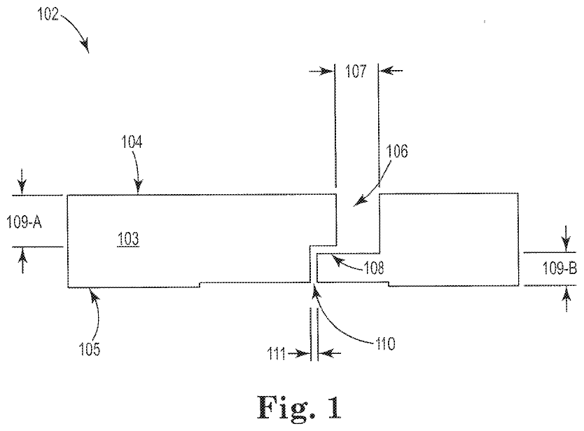

FIG. 1 illustrates an example of a heat-sink 102 including a chamber according to the disclosure. That heat-sink 102 is formed of a material that absorbs heat from a heat-generating component such as those described herein. For instance, a body of the heat-sink 102 can be formed of a material such as a metal, a ceramic, a composite material, and/or another heat-conductive material. Examples of metals include aluminum, copper, among others.

The heat-sink 102 includes a body 103. The body 103 can be shaped in a variety of possible configurations. In some examples, the heat-sink 102 can include an extended surface area for the dispersion of absorbed heat into the surrounding atmosphere and/or into another material, such as a liquid coolant. For instance, the body 103 can include a protrusion (not illustrated) such as a fin, rib, domes, or other features that protrude from a surface such as a first surface 104 and/or a second surface 105 of the body 103. As illustrated in FIG. 1, the first surface 104 is located on an opposite side of the body 103 of the heat-sink 102 from the second surface 105.

The body 103 of the heat-sink 102 can define various features such as a chamber 106, a channel 108, and/or an opening 110. It is understood that the chamber 106, channel 108, and the opening 100, while illustrated as visible from the surface of the heat-sink 102 are disposed within the body 103 of the heat-sink such that the chamber 106 and the opening 110 can be readily visible but the channel 108 can be partially or completely disposed within the body 103 of the heat-sink and therefore is not readily visible. That is, the chamber 106, the channel 108 and the opening 110 are each bounded by a surface/wall (omitted for ease of illustration) formed by the body 103 that permit that storage and ejection of TIM, as described herein.

As illustrated in FIG. 1, the body 103 can define the chamber 106 that extends from the first surface 104 through a portion 109-A of a total thickness (equal to a sum of 109-A and 109-B) of the body 103. Stated differently, the chamber 106 can extend through a portion 109-A of the total thickness of the body 103, but not all of, the total thickness of the body 103. Similarly, the channel as described herein, can extend through a portion 109-B of the total thickness of the body 103, but not all of, the total thickness of the body 103.

In some examples, the chamber 106 can be substantially rectangular, as illustrated in FIG. 1. As used herein, the term “substantially” means that sizes, parameters, and/or other quantities and characteristics may not be exact, but may be approximate and/or larger or smaller, reflecting tolerances, conversion factors, rounding off, measurement error and the like, and other factors known to those of skill in the art, but that are effective to achieve the intended function consistent with aspects of heat-sink chambers as described herein. Stated differently, a width 107 of the chamber 106 can be the same (e.g., as represented by an individual numeric value indicating a width) at any point(s) along the length (a direction orthogonal to the width 107) of the chamber 106. That is, the width 107 of the chamber 106, as illustrated in FIG. 1, can be substantially constant and/or the chamber 106 can have a length (element number omitted for ease of illustration) that is substantially constant across the width 107 of the chamber 106. However, the disclosure is not limited to such planar shapes. That is, the shape of the chamber 106 and/or the channel 108, among other features such as the angle of the walls can be varied.

The chamber 106 can have a volume in a range of from 1000 cubic centimeters (cc) to 0.1 cc. All individual values and sub-ranges from 1000 to 0.1 cc are included. For example, the chamber 106 can have a volume in a range of from an upper value of 1000, 900, 800, 700, 600, 500, or 400 cc to a lower limit of 300, 200, 100, 50, 30, 15, 10, 5 1, 0.5, or 0.1 cc. In some examples, the chamber 106 can have a volume equal to or greater than an amount of TIM to be disposed in the chamber 106. That is, as detailed herein, the chamber 106 can have a volume that is sized to permit TIM to be disposed in and ejected, via the channel 108 and the opening 110, from the chamber 106.

As mentioned, the body 103 can define the channel 108. The channel can extend through a portion 109-B of the total thickness 109 of the body 103. The channel 108 can be in fluid communication with the chamber 106 and the opening 110. As used herein, being in “fluid communication” refers to components that are directly or indirectly coupled to permit the transfer of a fluid or other substance, when present, between the components. For example, as detailed herein a TIM, when present, can be transferred between the chamber 106, the channel 108, and the opening 110.

In various examples the portion 109-A and the portion 109-B can be equal and/or substantially equal to the total thickness 109 of the body 103. For example, the second surface 105 can define an opening 110 have a width 111. In such examples the channel 108 can extend from the chamber 108 through a remaining portion (equal to portion 109-B) of the total thickness 109 of the body 103 to the opening 110 to couple the chamber 106 to the opening 110.

In various examples, the chamber 106 can have a different width, different length, different shape, and/or different volume than a corresponding width, length, shape, and/or volume of the channel 108. For instance, the chamber 106 can have a width 107 that is greater than a width 111 of the channel 108, as illustrated in FIG. 1. Having the width 107 of the chamber that is greater than the width 111 of the channel can promote aspects of heat-sink chambers, for instance, facilitating surface tension of the TIM, when present, to be sufficient to retain the TIM in the chamber, channel, and/or opening, rather than other configurations having the TIM be inadvertently emitted from the heat-sink 102 to an environment surrounding the heat-sink 102. In this way, the TIM can be stored in the heat-sink 102 until the TIM is ejected by an ejection mechanism such as those described herein. Though it is noted that the disclosure is not limited to the configuration illustrated in FIG. 1, and rather that other configurations are possible.

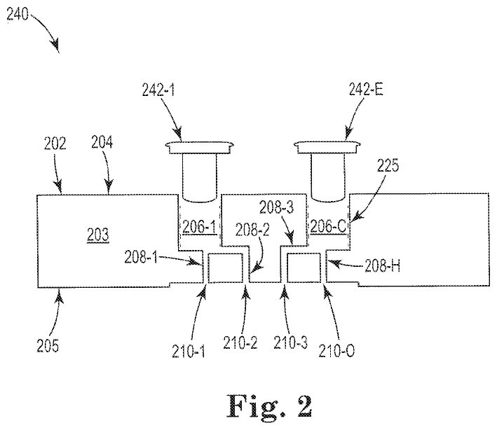

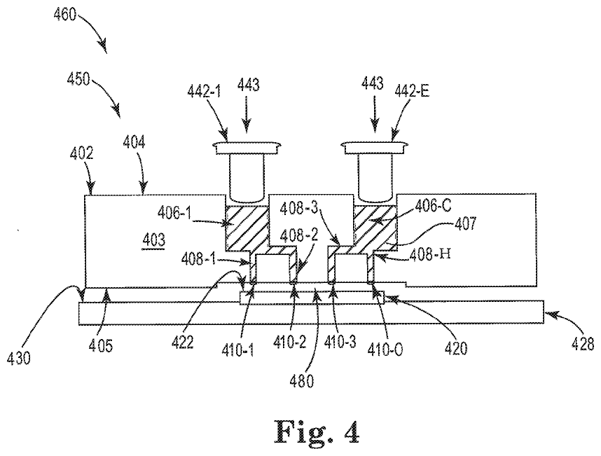

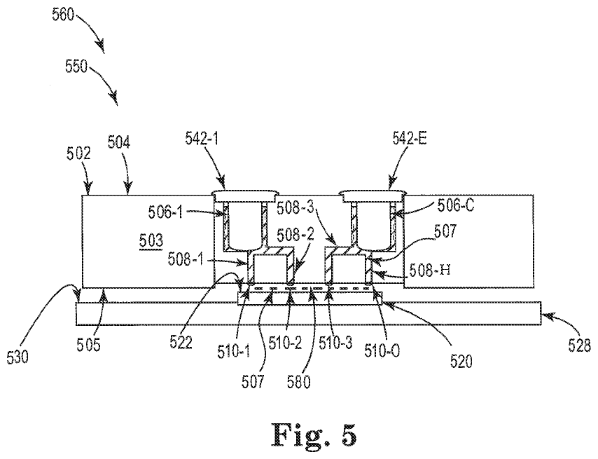

As mentioned, the body 103 can define an opening such as the opening 110 in the second surface 105 of the body 103. The opening 110 can be located substantially at the middle of the heat-sink 102. As used herein, the middle of the heat-sink refers to a middle point taken along a width of the heat-sink 102 (as taken along an axis parallel to the axis taken along width 107), as illustrated in FIG. 1. Having the opening 110 located substantially at the middle of the heat-sink 102 can promote ejection of TIM, when present, into a center of a space between the body 103 and another component positioned adjacent to the body 103. The component positioned adjacent to the heat-sink can be a heat-generating component, as detailed herein with respect to FIGS. 4 and 5. However, in various examples, the opening 110 can be located a different location than the middle of the heat-sink 102 and/or include additional openings (such as those described in FIGS. 2-5) that are at a different location than the middle of the heat-sink 102.

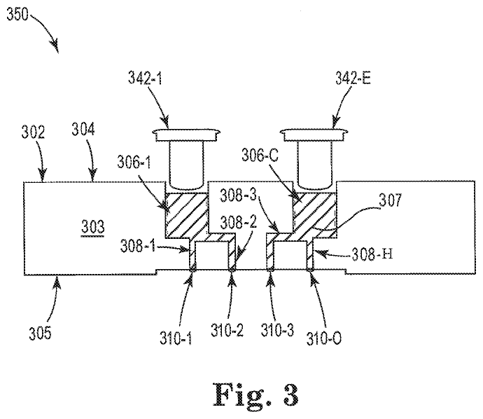

FIG. 2 illustrates an example of a heat-dissipation system 240 with a heat-sink 202 including a chamber according to the disclosure. As illustrated in FIG. 2, the heat-dissipation system 240 can include a heat-sink 202 and an ejection mechanism such as ejection mechanisms 242-1, . . . , 242-E, among other possible components. The heat-dissipation system 240 can include a TIM, as described herein with respect to FIG. 3.

The heat-sink 202 can be analogous or similar to heat-sink 102, 302, 402, and/or 502, as described with respect to FIGS. 1, 3, 4, and 5. For instance, the heat-sink can include a body 203. The body 203 can define a chamber such as chambers 206-1, . . . , 206-C (collectively referred to herein as chambers 206), a channel such as channels 208-1, 208-2, 208-3, . . . 208-H (collectively referred to herein as channels 208), and an opening such as openings 210-1, 210-2, 210-3, . . . , 210-0 (collectively referred to herein as openings 210). That is, as illustrated in FIG. 2, the heat-sink 202 can include a first surface 204, a second surface 205, a plurality of chambers 206, a plurality of channels 208, and a plurality of openings 210.

Chambers 206-1, . . . , 206-C can be analogous or similar to chamber 106, 306-1, . . . , 306-C. 406-1, . . . , 406-C. and/or 506-1, . . . , 506-C, as described herein with respect to FIGS. 1, 3, 4, and 5. Similarly, channels 208-1, 208-2, 208-3 . . . . , 208-H can be analogous or similar to channel 108, 308-1, 308-2, 308-3, . . . , 308-H, 408-1, 408-2, 408-3, . . . , 408-H, and/or 508-1, 508-2, 508-3 . . . . , 508-H, as described herein with respect to FIGS. 1, 3, 4, and 5. Openings 210-1, 210-2, 210-3, . . . , 210-0 can be analogous or similar to opening 110, 310-1, 310-2, 310-3 . . . . , 310-0, 410-1, 410-2, 410-3, . . . , 410-0 and/or 510-1, 510-2, 510-3, . . . , 510-0, as described herein with respect to FIGS. 1, 3, 4, and 5. While a given number of chambers, channels, and openings are illustrated, it is understood that a total number and/or relative number of the chambers, channels, and openings can be varied. For instance, a respective number of channels and/or openings per chamber can be varied, among other possibilities.

In some examples, the openings 210 can be spaced a uniform distance apart from each other, as illustrated in FIG. 2. Stated differently, in some examples each opening of the plurality of openings can be spaced a uniform distance apart from an adjacent opening in the plurality of openings. For example, each opening can be the same distance (e.g., 1 millimeter) from an adjacent opening. Having the openings 210 uniformly spaced can promote uniform ejection of TIM, when present, from the heat-sink 202.

The openings 210 can have the same or different widths, shapes, and/or circumference. In some examples, openings (e.g., openings 210-2 and/or 210-3) located at a more central location of a heat-sink can include a larger width and/or larger circumference to permit ejection a greater portion of TIM, when present in the heat-sink, from the heat-sink than other openings (e.g., 210-1 and/or 210-)) which a less proximate to a central location of the heat-sink and therefore have a relatively smaller width and/or circumference. Having openings with such different sized and/or shaped openings can promote transfer to TIM to a center of a component/space adjacent from the heat-sink and/or reduce a likelihood of the TIM being displaced from a space between the heat-sink and another component such as a heat-generating component.

As mentioned, the heat-dissipation system 240 can include an ejection mechanism such as ejection mechanisms 242-1, . . . , 242-E (collectively referred to as ejection mechanism 242). The ejection mechanism 242 can be analogous or similar to ejection mechanisms 342-1, . . . , 342-E, 442-1, . . . , 442-E, and/or 542-1, . . . , 542-E as described herein with respect to FIGS. 3, 4, and 5, respectively. As illustrated in FIG. 2, each chamber can include a corresponding ejection mechanism. For instance, ejection mechanism 242-1 can correspond to chamber 206-1, while ejection mechanism 242-E can correspond to chamber 206-C. In this way, each ejection mechanism can displace TIM, when present in the corresponding chamber, and thereby cause the displaced TIM to be ejected from the heat-sink 202.

The ejection mechanism 242 can be formed of a screw or other component that can be movably coupled to the body 203. As used herein, being “movably coupled” refers to first component being permanently or removably coupled to a surface of a second component in a manner to permit movement of the first component relative to the second component. For instance, as illustrated in FIG. 2, the chambers 206 can be threaded (illustrated as 225) or include another mechanical component to permit the ejection mechanism 242 (e.g., a screw) to be movably coupled to the heat-sink 202. When movably coupled, the ejection mechanism (e.g., ejection mechanism 242-1) can be moved into a volume of chamber (e.g., chamber 206-1) and thereby cause TIM, when present, to be displaced from the chamber. The displaced TIM can be ejected via a channel (e.g., channel 208-1 and/or 208-2) and an opening (210-1 and/or 210-2). While ejection mechanisms 242 are illustrated as screws, it is understood that other types of ejection mechanisms such as plungers, rods, and/or other components capable of being movably coupled to a heat-sink as described herein are possible.

FIG. 3 illustrates another example of a heat-dissipation system 350 with a heat-sink including a chamber according to the disclosure. As illustrated in FIG. 3, the heat-dissipation system 350 can include a heat-sink 302, ejection mechanisms 342-1, . . . , 342-E, and a TIM 307.

As mentioned, the heat-sink 302 can include a body 303 with a first surface 304 and a second surface 305. The body can define chambers 306-1, . . . , 306-C (collectively referred to herein as chambers 342), channels 308-1, 308-2, 308-3, . . . , 308-H (collectively referred to herein as channels 308), and openings 310-1, 310-2, 310-3, . . . , 310-0 (collectively referred to herein as openings 310). Each of the chambers 306 can extend from the first surface 304 through a portion of a total thickness of the body 303. Each of the openings 310 can be formed in the second surface 305. Each channel 308 can extend through a remaining portion of the total thickness of the body (relative to the portion of the body through which the chambers extends) to couple the opening 310 with the chamber 306. That is, as illustrated in FIG. 3, the chambers 306 are in fluid communication with the channels 308 and the openings 310.

In various examples, the heat-dissipation system 350 can include a TIM (illustrated as 307). As used herein a TIM refers to a material that is inserted between two components to enhance the thermal coupling between them. Examples of TIMs include thermal gels, thermal greases, thermal pastes, and thermal oils. In some examples, the TIM can be a liquid metal and/or liquid metal alloy such as a copper alloy, an aluminum, and/or an aluminum alloy. That is, as illustrated in FIG. 3, each chamber of the plurality of chambers 306 can include an amount of TIM (illustrated as 307) disposed in the chamber; and a respective channel and opening to permit ejection of TIM disposed in the chamber. An amount of the TIM disposed in the chambers 306 can be equal to, less than, or greater than a volume of a space (e.g., space 480 as described with respect to FIG. 4) between the heat-sink 402 and another component.

The TIM 307 can be disposed in the chambers 306, in the channels 308, and/or in the openings 310. As used herein, “disposed” means a location at which something is physically positioned. In various examples the TIM 307 can be disposed in the heat-sink 302, until the TIM is caused to be ejected from the heat-sink 302 responsive to movement of the ejection mechanisms 342. For instance, as illustrated in FIG. 3, the TIM 307 can be disposed in the chamber 306, the channels 308, and the openings 310.

As illustrated in FIG. 3, the surface tension of the TIM 307 can inherently cause the TIM 307 to be retained in the heat-sink until the TIM is caused to be ejected from the heat-sink 302 responsive to movement of the ejection mechanisms 342. However, in some examples a capping material (not shown in FIG. 3) can be disposed over the openings 310 to promote storage of the TIM 307 in the heat-sink. Examples of capping material include foil, plastics, laminated structures, plugs, among other types of capping material suitable to promote the storage in and subsequent ejection of the TIM 307 from the heat-sink 302.

In some example, the ejection mechanism 342 can have a total travel distance (e.g., from a first position as illustrated in FIG. 4 to a second position as illustrated in FIG. 5) that corresponds to a predetermined volume of the TIM to be ejected via the opening 310. That is, be varying a travel distance of an ejection mechanism 342, an amount/type of TIM, a size/shape of the channel, channel, and/or ejection mechanism, etc., an amount of TIM ejected from the heat-sink 402 can be predetermined and controlled to ensure a suitable amount of TIM is ejected from the heat-sink 402 depending, for instance, on an application of the heat-sink 402 and/or type of computing device in which the heat-sink 402 can be employed.

FIG. 4 illustrates an example of a computing device 460 including a heat-dissipation system 450 with a heat-sink including a chamber according to the disclosure. The computing device 460 can be a mobile phone, a wearable computing device, a tablet, a laptop computer, a desktop computer, or combinations thereof, among other possible types of computing devices.

As mentioned, the heat-dissipation system 450 can include a heat-sink 402, ejection mechanisms 442-1, . . . , 442-E, and a TIM 407. The heat-sink 402 can include a body 403 with a first surface 404 and a second surface 405. The body 403 can define chambers 406-1, . . . , 406-C (collectively referred to herein as chambers 406), channels 408-1, 408-2, 408-3, . . . , 408-H (collectively referred to herein as channels 408), and openings 410-1, 410-2, 410-3, . . . , 410-0 (collectively referred to herein as openings 410).

As illustrated in FIG. 4, the computing device 460 can include a heat-generating component 420 disposed on a circuit board 428. For instance, the heat-generating component 420 can be disposed on a first surface 430 of the circuit board 428. The circuit board 428 (i.e., a main circuit board) refers to circuitry which includes or is coupled to an operation system of the computing device 460. For example, the circuit board 428 can be a printed circuit board (PCB), among other possibilities.

As mentioned, the heat-generation component 420 can be a central processing unit, a graphics processing unit, or a power source, among other components that generate heat during operation of the computing device 460. A power source refers to a source of direct current (DC) and/or a source of alternating current (AC). Examples of power sources include batteries, AC/DC power converters, and/or DC/AC power converters, among other types of power sources.

The heat-generating component 420 can include a plurality of surfaces such as a first surface 422. The first surface 422, as illustrated in FIG. 4, can be on the opposite side from another surface of the heat-generating component 420 that is coupled to the first surface 430 of the circuit board 428. The first surface 422 can, in part, define a space (illustrated as 480) between the heat-generating component and the heat-sink 402. That is, the space 480 can be defined by, or in part by, the first surface 422 of the heat-generating component 420 and the second surface 405 of the heat-sink 402. For instance, a volume of the space 480 can be equal to a volume between the first surface 422 of the heat-generating component 420 and the second surface 405 of the heat-sink 402. While illustrated as being disposed a distance apart, in some examples, a portion of the first surface 422 of the heat-generating component 420 can be in contact with an adjacent portion of the second surface 405 of the heat-sink 402.

As illustrated in FIG. 4, the heat-dissipation system 450 can include a TIM (illustrated as 407). The TIM 407 can be disposed in the chambers 407 and/or in the channels 408. That is, in some examples, the space 480 can be free of any TIM 407, as illustrated in FIG. 4. In some examples, the TIM 407 can be ejected responsive to a force (illustrated as 443) applied to the ejection mechanisms 442. That is, the force 443 can cause the ejection mechanism 442 to move from a first position at which the TIM 407 is stored in the chambers 407 and/or channels 408 (as illustrated in FIG. 4) to a second position in which the TIM is ejected from the heat-sink (as illustrated in FIG. 5.

That is, FIG. 5 illustrates another example of a computing device 560 including a heat-dissipation system 550 with a heat-sink including a chamber according to the disclosure. The computing device 560 can be analogous or similar to computing device 460 as described with respect to FIG. 4. For instance, the computing device 560 can include a heat-generating component 520 disposed on a first surface 530 of the circuit board 520. The heat-generating component 520 can include a plurality of surfaces including a first surface 522. As illustrated in FIG. 5, the first surface 522 can be positioned a distance away from the heat-sink 502 to define a space 580 between the heat-generating component 520 and the heat-sink. As detailed herein, TIM can be ejected from the heat-sink 202 into the space 580.

For instance, the heat-dissipation system 550 can include a heat-sink 502, ejection mechanisms 542-1, . . . , 542-E, and an amount of a TIM 507 that can be ejected into the space 580. The heat-sink 502 can include a body 503 with a first surface 504 and a second surface 505. The body 503 can define chambers 506-1, . . . , 506-C (collectively referred to herein as chambers 506), channels 508-1, 508-2, 508-3, . . . , 508-H (collectively referred to herein as channels 508), and openings 510-1, 510-2, 510-3, . . . , 510-0 (collectively referred to herein as openings 510).

FIG. 5 illustrates the ejection mechanism 542 at a second position (subsequent to the application of a force as described with respect to FIG. 4). That is, the ejection mechanisms 542 can be shaped and/or sized to eject some or all of the TIM 507 from the chambers 506. In any case, the TIM 507 can be ejected into and disposed in the space 580, as illustrated in FIG. 5 (dashed lines representing TIM 507 disposed in the space 580). Having the TIM 507 ejected into and disposed in the space 580 can promote heat-dissipation. For instance, heat generated by the heat-generating component 520 can transfer from a first surface 522 of the heat-generating component through the TIM 507 disposed in the space 580 into the heat-sink 502. In some examples, the TIM 507 can fill an entirety of a volume of the space 580.

It will be understood that when an element is referred to as being “on,” “connected to”, “coupled to”, or “coupled with” another element, it can be directly on, connected, or coupled with the other element or intervening elements can be present. In contrast, when an object is “directly coupled to” or “directly coupled with” another element it is understood that are no intervening elements (adhesives, screws, other elements) etc.

In the foregoing detailed description of the disclosure, reference is made to the accompanying drawings that form a part hereof, and in which is shown by way of illustration how examples of the disclosure can be practiced. These examples are described in sufficient detail to enable those of ordinary skill in the art to practice the examples of this disclosure, and it is to be understood that other examples (e.g., having different thickness) can be utilized and that process, electrical, and/or structural changes can be made without departing from the scope of the disclosure.

The figures herein follow a numbering convention in which the first digit corresponds to the drawing figure number and the remaining digits identify an element or component in the drawing. For example, reference numeral 102 can refer to element 102 in FIG. 1 and an analogous element can be identified by reference numeral 202 in FIG. 2. Elements shown in the various figures herein can be added, exchanged, and/or eliminated to provide additional examples of the disclosure. In addition, the proportion and the relative scale of the elements provided in the figures are intended to illustrate the examples of the disclosure, and should not be taken in a limiting sense.

What is claimed:

1. A heat-sink comprising:
a body having a first surface and a second surface opposite the first surface, wherein the body defines:
a chamber that extends from the first surface through a portion of a total thickness of the body;
an opening in the second surface; and
a channel that extends from the chamber through a remaining portion of the total thickness of the body to the opening to couple the chamber to the opening.

2. The heat-sink of claim 1, wherein a width of the chamber is greater than a width of the channel.

3. The heat-sink of claim 1, wherein the opening is located substantially at a middle of the heat-sink.

4. The heat-sink of claim 1, wherein a volume of the chamber is in a range of from 1000 cubic centimeters (cc) to 0.1 cc.

5. The heat-sink of claim 1, wherein the chamber includes threads to receive a screw ejection mechanism.

6. A heat-dissipation system comprising:
a heat-sink including a body defining a chamber, a channel, and an opening, wherein the chamber extends from a first surface of the body through a portion of a total thickness of the body is coupled via the channel that extends from the chamber through a remaining portion of the total thickness of the body to the opening to couple the chamber to the opening:
a thermal interface material (TIM) disposed in the chamber; and
an ejection mechanism that is movable into a volume of the chamber to cause the TIM to be ejected via the opening.

7. The heat-dissipation system of claim 6, wherein the ejection mechanism is a screw.

8. The heat-dissipation system of claim 6, wherein the heat-sink further is formed of a metal.

9. The heat-dissipation system of claim 6, wherein the TIM includes a liquid metal.

10. The heat-dissipation system of claim 6, wherein the ejection mechanism has a total travel distance that corresponds to a predetermined volume of the TIM to be ejected via the opening.

11. A computing device comprising:
a heat-generating component; and
a heat-dissipating system including:
a heat-sink having a body with a first surface and a second surface, wherein the body defines:
a chamber that extends from the first surface through a portion of a total thickness of the body;
an opening in the second surface; and
a channel that extends through a remaining portion of the total thickness of the body to couple the opening with the chamber;
a thermal interface material (TIM) disposed in the chamber, and
an ejection mechanism is movable to displace the TIM in the chamber and thereby cause the TIM to be ejected via the opening into a space between the heat-generating component and the body.

12. The computing device of claim 11, wherein the chamber is included in a plurality of chambers, wherein each chamber of the plurality of chambers includes:
an amount of TIM disposed in the chamber; and
a respective channel and opening to permit ejection of TIM disposed in the chamber into the space between the heat-generating component and the body.

13. The computing device of claim 11, wherein the opening is included in a plurality of openings.

14. The computing device of claim 13, wherein each opening of the plurality of openings is spaced a uniform distance apart from an adjacent opening in the plurality of openings.

15. The computing device of claim 11, wherein the heat generating component is a central processing unit, a graphics processing unit, or a power source.
